(19) United States
(12) Patent Application Publication
(10) Pub. No.: US 2010/0311238 A1
(43) Pub. Date: Dec. 9, 2010

(54) METHOD OF FORMING COPPER WIRING LAYER

(76) Inventors: Hiroki Nakamura, Ageo-shi (JP); Masaki Kado, Saitama-shi (JP); Shigeru Aomori, Kashiwa-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/859,018

(22) Filed: Aug. 18, 2010

Related U.S. Application Data
(62) Division of application No. 11/344,014, filed on Feb. 1, 2006.

(30) Foreign Application Priority Data
Feb. 4, 2005 (JP) 2005-028919

(51) Int. Cl. H01L 21/768

(52) U.S. Cl. 438/653; 257/E21.584

(57) ABSTRACT

A method of forming a copper wiring layer, which includes forming a pattern of copper seed layer on a substrate, and forming a copper wiring pattern on the pattern of copper seed layer by means of electroless plating. At least one component of semiconductor device selected from the group consisting of the gate electrode, the source electrode, the drain electrode, and a wiring connected with at least one of these electrodes is formed by a method comprising forming a pattern of copper seed layer, and forming a copper wiring pattern on the pattern of copper seed layer by means of electroless plating.

### CROSS-REFERENCE TO RELATED APPLICATIONS

This application is a divisional application of U.S. application Ser. No. 11/344,014, filed Feb. 1, 2006, and is based upon and claims the benefit of priority from prior Japanese Patent Application No. 2005-028919, filed Feb. 4, 2005, the entire contents of both of which are incorporated herein by reference in their entirety.

### BACKGROUND OF THE INVENTION

1. Field of the Invention

This invention relates to a method of forming a copper wiring layer, which is capable of forming a fine wiring of low resistance, to a method of manufacturing a semiconductor device. In particular, this invention relates to the formation of a copper wiring layer which is suited to the manufacture of a display device represented by a liquid display device as well as for the manufacture of a semiconductor device such as a ULSI.

2. Description of the Related Art

Generally, aluminum (Al) or alloys thereof are employed as a wiring material in a semiconductor device represented by an LSI and ULSI. However, due to demands for further refinement of the wiring or of the line width of wiring in order to meet a trend to further increase the integration of semiconductor elements in recent years or demands for the enhancement of operating speed, now under study is an employment of copper (Cu), which is lower in electric resistance than Al wiring and high in resistance to electromigration or stress migration, as a material for the wiring or electrodes of the next generation.

Further, even in the field of a display device represented by a liquid crystal display device, due to demands for the elongation of wiring in conformity with the enlargement in area of display screen or demands for enhancement of monolithic integrated circuit such as a driver circuit and in-pixel memory can be mounted thereon, there is increasing demands for a wiring of low electric resistance as demanded in the field of semiconductor devices.

The processing for forming a fine copper wiring cannot be satisfactorily performed by simply following the conventional technique of forming an Al wiring, wherein a masking technique employing a photo engraving process (PEP) or so-called photolithography is employed in combination with an etching technique such as reactive ion etching (RIE). Namely, the vapor pressure of copper halides is much lower than that of aluminum halides, so that copper halides can hardly be vaporized. Therefore, if it is desired to perform the etching of copper by making use of an etching technique such as RIE, the temperature of the substrate is required to be raised to 200 to 300° C. or more, thus raising many problems to be solved before such an etching technique is actually realized. Additionally, it is also required in this case to employ not the ordinary photo-mask but a mask made of SiO₂ or SiNₓ.

In view of these problems, there has been proposed a method of forming a copper wiring layer by making use of a damascene method as disclosed in JP Patent Laid-open Publication (Kokai) No. 2001-189295 (2001) or No. 11-135504 (1999). According to this damascene method, a copper wiring layer is formed by the following process.

First of all, a silicon oxide layer is formed as an insulating layer on a substrate and a wiring trench corresponding to a desired wiring pattern is formed in advance in this insulating layer. Then, a diffusion prevention layer consisting of TaN, Ta, TiN, etc., is formed as an underlying layer of the copper wiring layer in order to prevent copper from diffusing into the silicon oxide layer.

Thereafter, by making use of any desired method for depositing copper on the diffusion preventing layer to fill the wiring trench with the copper such as a physical vapor deposition (PVD) (such as sputtering), a plating method, or chemical vapor deposition (CVD) using an organometallic material, a thin copper layer for creating the copper wiring layer is formed all over the surface of the insulating layer, thereby concurrently filling the trench with the thin copper layer. Subsequently, by making use of a suitable method such as a polishing method, e.g. chemical mechanical polishing (CMP), or an etch-back technique, the thin copper layer is abraded until the underlying insulating layer (the upper edge of the trench) is exposed, thereby forming a wiring pattern consisting of the copper that has been buried in the trench. Finally, an insulating layer or a metallic layer capable of exhibiting a diffusion prevention function is formed on the copper wiring layer.

However, the damascene method disclosed in JP Patent Laid-open Publication (Kokai) No. 2001-189295 (2001) is accompanied with the following problems. Namely, in addition to the step of forming a trench for burying at least the copper wiring, it requires a large number of steps including film-forming steps for forming a metallic diffusion prevention layer, a metallic seed layer, a metallic wiring layer and an abrasion prevention layer; a photolithography step; an etching step; and a polishing step. As a result, the manufacturing process involved in this damascene method would become very complicated, resulting in increase in manufacturing cost.

Furthermore, in order to reduce the electric resistance of wiring, it is necessary to increase the cross-sectional area of wiring. However, because of necessity to enhance the integration of semiconductor elements, there is restriction in any attempt to increase the cross-sectional area of wiring. It may be conceivable to employ a trench or via-hole of high aspect ratio (i.e. narrow in width or diameter and large in depth) as a method for increasing the cross-sectional area of wiring without badly affecting the enhancement of the integration of semiconductor elements. However, it is difficult to fill a trench or a via-hole which is narrow in width and large in depth with copper, resulting in insufficient filling of copper. Further, the step of CMP to polish the copper thin film that has been formed all over the surface of substrate in advance to thereby remove a redundant portion of copper so as to flatten the surface is accompanied with a problem that it takes a long time for accomplishing the treatment, thus degrading the throughput.

Although there has been developed a large-scale CMP device which is capable of coping with a semiconductor wafer of large diameter having a diameter of 12 inches or so, it is not yet succeeded to develop a CMP device which can be practically used for treating a display device using a rectangular glass substrate having a larger surface than that of the aforementioned semiconductor wafer. Further, in the case of a display device such as a large scale liquid crystal display device in particular, even if it is possible to form a copper wiring layer by making use of a whole surface polishing using the aforementioned CMP or by making use of etching method, most of the copper thin film that has been formed advance is caused to remove and discard since the portion of thin copper layer that can be utilized as a wiring is very small as compared with the surface of glass substrate. As a result, the utilization efficacy of expensive copper resource to be employed as a wiring material is extremely degraded, thus increasing the manufacturing cost of display device, resulting in an increase of product price.

As for the technique of forming a copper wiring, which makes it possible to effectively utilize the copper resource, there has been proposed a technique as disclosed in JP Patent Laid-open Publication (Kokai) No. 2004-134771 (2004). According to this technique, a copper plating film can be formed only on a copper wiring region, thereby making it possible to reduce the manufacturing cost.

However, this technique is accompanied with problems if the conductive regions of a circuit provided with a thin film transistor such as the wiring layer, electrodes, electrode pads thereof are to be formed with an electrolytically plated copper layer. Namely, in addition to the step for separating the wiring layer, the electrodes and the electrode pads from each other in a subsequent process, it is also necessary to employ a high-voltage application method for electrolytic plating, which takes into consideration the distance from the peripheral electrodes for electrolytic plating or the generation of non-uniformity of film thickness due to a distribution of current density in the case of using a large substrate, or the influence on the semiconductor elements such as transistors or capacitors.

### BRIEF SUMMARY OF THE INVENTION

It is an object of the present invention to provide a method of forming a copper wiring layer and a method of manufacturing a semiconductor device, which make it possible to form a copper wiring layer in every conductive regions all over a wide region.

According to a first aspect of the present invention, there is provided a method of forming a copper wiring layer, which comprises forming a pattern of copper seed layer on a substrate; and forming a copper wiring pattern on the pattern of copper seed layer by means of electroless plating.

According to a second aspect of the present invention, there is provided a method of forming a semiconductor device, which comprises forming a semiconductor layer on a substrate; forming a gate insulating film and a gate electrode on the semiconductor layer; forming a source region and a drain region by introducing an impurity into the semiconductor layer with the gate electrode being used as a mask; and forming a source electrode connected with the source region and a drain electrode connected with the drain region; wherein at least one component selected from the group consisting of the gate electrode, the source electrode, the drain electrode, and a wiring connected with at least one of these electrodes is formed by a method comprising forming a pattern of copper seed layer; and forming a copper wiring pattern on the pattern of copper seed layer by means of electroless plating.

According to a third aspect of the present invention, there is provided a copper wiring layer comprising a pattern of copper seed layer formed on a substrate; and a copper wiring pattern formed on the pattern of copper seed layer by means of electroless plating.

According to a fourth aspect of the present invention, there is provided a semiconductor device comprising a transistor provided, on a substrate thereof, a source region, a drain region, a channel region located between the source region and drain region, a gate insulating film and a gate electrode both formed on the channel region, a source electrode connected with the source region, and a drain electrode connected with the drain region; and a wiring layer connected with the gate electrode, with the source electrode and with the drain electrode; wherein at least one component selected from the group consisting of the gate electrode, the source electrode, the drain electrode, and a wiring connected with at least one of these electrodes comprises a pattern of copper seed layer, and a copper wiring pattern formed on the pattern of copper seed layer by means of electroless plating.

Incidentally, the term “copper wiring layer” appearing in this specification is intended to include not only a wiring for transmitting an electric current between two points separated from each other but also any kind of conductive regions such as electrodes including the source electrode, the drain electrode and the gate electrode; the electrode pad; and the lead-out wire.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIGS. 1A to 1J are cross-sectional views illustrating, in stepwise, one example of the method for forming a copper wiring layer according to one embodiment of the present invention;

FIGS. 2A to 2C are cross-sectional views illustrating, in stepwise, another example of the method for forming a copper wiring layer according to one embodiment of the present invention;

FIGS. 3A to 3H are cross-sectional views illustrating, in stepwise, a further example of the method for forming a copper wiring layer according to one embodiment of the present invention;

FIG. 4 is a flow chart illustrating, in stepwise, a method for manufacturing a semiconductor device according to another embodiment of the present invention;

FIG. 5 is a diagram showing the construction of a crystallization apparatus for explaining the process of crystallization in the steps shown in FIG. 4;

FIG. 6 is a diagram showing the construction of an illumination system shown in FIG. 5; and

FIG. 7 is a cross-sectional view for illustrating the construction of the semiconductor device that has been manufactured by the process shown in FIG. 4.

### DETAILED DESCRIPTION OF THE INVENTION

There is known a method to directly form a copper layer on a barrier layer formed in advance on a substrate by means of electroless plating after forming palladium nuclei on the barrier layer by treatment of palladium catalyst. In this method, however, the copper layer is plated only on the palladium nuclei (several nm to several tens nm). Where the plated copper film is very thin, therefore, it is difficult to form a continuous copper film if it were not to form the palladium nuclei in high density. Therefore, it is difficult to form a plated copper layer having a uniform thickness on a surface of large area.

In the present invention, however, the aforementioned problems are completely dissolved by forming a copper wiring pattern by means of electroless plating on a pattern of a copper seed layer formed in advance on the surface of substrate.

In this case, the formation of a pattern of copper seed layer is performed by the steps of forming a copper seed layer on the surface of substrate, and etching the copper seed layer into a wiring pattern. Further, the formation of a pattern of copper seed layer is performed by the steps of forming at least one layer having a wiring pattern on the copper seed layer, said at least one layer having a wiring pattern being selected from a resist layer, an insulating layer and a metallic layer; and etching the copper seed layer with said at least one layer having a wiring pattern being employed as a mask.

It is preferable that the crystal face of the copper seed layer may be oriented mainly in (111) plane.

In the method of forming a copper wiring layer according to a first aspect of the present invention, an underlying barrier layer is formed between the substrate and the copper seed layer, and the underlying barrier layer is etched by making use of the copper wiring pattern as a mask. Further, a capping metal layer may be formed on a surface of the copper wiring pattern in order to prevent the diffusion of copper.

The aforementioned method of forming a copper wiring layer can be applied to the formation of at least one component selected from the group consisting of the gate electrode, the source electrode, the drain electrode, and a wiring connected with at least one of these electrodes.

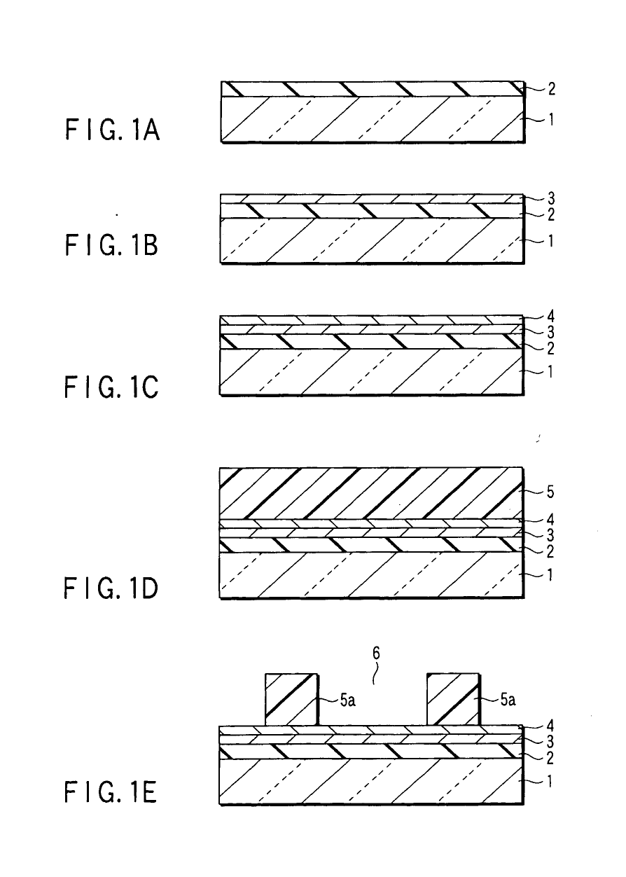

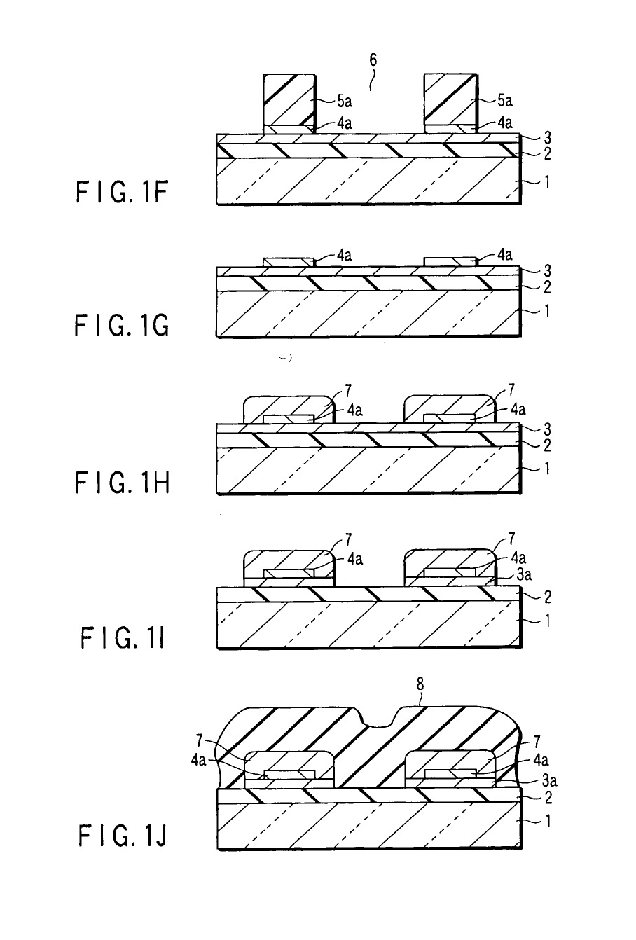

Next, the method of forming a copper wiring layer according one aspect of the present invention will be explained with reference to FIGS. 1A to 1J. FIGS. 1A to 1E are cross-sectional views illustrating, in stepwise, a process of forming a resist pattern for working a copper seed layer. FIGS. 1F to 1J are cross-sectional views illustrating, in stepwise, a process of forming a copper wiring layer through the etching of the copper seed layer by making use of the resist pattern formed in the process shown in FIGS. 1A to 1E.

In FIGS. 1A to 1J, the same portions or components are identified by the same reference numbers, thereby omitting the repeated explanation thereof. In this specification, the term “copper wiring layer” is intended to include every conductive regions such as an electric wiring for effecting electric connection between circuit elements such as transistors, and the electrodes and terminals (pads) of transistor, etc.

In the method according to this embodiment, a copper seed layer is formed in advance in a form of wiring pattern, and then electroless plating is applied to the surface of the copper seed layer, thereby making it possible to form a copper plating layer only on the surface of every copper seed layer. According to this method, since a copper wiring layer is formed through electroless plating after finishing the patterning of a copper seed layer, it is possible to more effectively inhibit the scattering of film thickness resulting from differences in width of pattern and prevent the disconnection of wiring and the generation of leak current between a lower wiring layer and an upper wiring layer as compared with the case where a plating film is to be formed inside a trench.

First of all, as shown in FIG. 1A, in order to prevent the permeation of impurities from a substrate 1, an underlying insulating layer 2 for example SiN (silicon nitride) film is formed on the substrate 1 to a thickness of 300 nm for example. As for the material for the substrate 1, it is possible to employ a conductor, an insulator or a semiconductor. This SiN film 2 can be formed on a glass substrate 1 having a relatively flat surface by means of plasma CVD method.

Then, as shown in FIG. 1B, an underlying barrier layer 3 is formed on the relatively flat surface of the underlying insulating layer 2. As for the underlying barrier layer 3, it is possible to employ at least one kind of barrier metal which is capable of suppressing the diffusion of copper and is excellent in adhesion to the underlying insulating film 2, such as Ta, TaN, TiN, TaSiN, etc. These barrier metals may be deposited on the underlying insulating film 2 to a thickness of, for example, about 30 nm by means of sputtering.

The formation of a copper seed layer:

First of all, as shown in FIG. 1C, a metallic seed layer containing copper as a major component for example a copper seed layer 4 is formed on the surface of the underlying barrier layer 3 having a relatively flat surface. As for the method of forming the copper seed layer 4, it is possible to employ a sputtering method for instance. This copper seed layer 4 may be formed to a thickness ranging from 30 nm to 300 nm for example. It is desirable that the crystal face of the copper seed layer 4 is oriented mainly in (111) plane.

Then, as shown in FIG. 1D, a photoresist layer 5 is formed on the copper seed layer 4. The method of forming the photoresist layer 5 may be a spin-coating method for example and the thickness of photoresist layer 5 may be 1.2 μm for example.

After the photoresist layer 5 is cured, the substrate 1 is delivered to an exposure device, wherein the photoresist layer 5 is subjected to exposure through an exposure mask having any optional pattern such as a predetermined electrode pattern, a desired wiring-forming pattern or a pad-forming pattern. After the step of exposure, the photoresist layer 5 is subjected to a developing treatment to form a photoresist pattern 5a having a desired wiring pattern as shown in FIG. 1E.

Then, as shown in FIG. 1F, the portions of copper seed layer 4 that have been exposed through the openings 6 of photoresist pattern 5a are removed by means of etching for instance to form a pattern 4a of copper seed layer. As for the etching method of the copper seed layer 4, it is possible to employ a wet etching method. Since the thickness of copper seed layer 4 is small, the etching of copper seed layer 4 can be easily performed, thus making it possible to suppress the side etching.

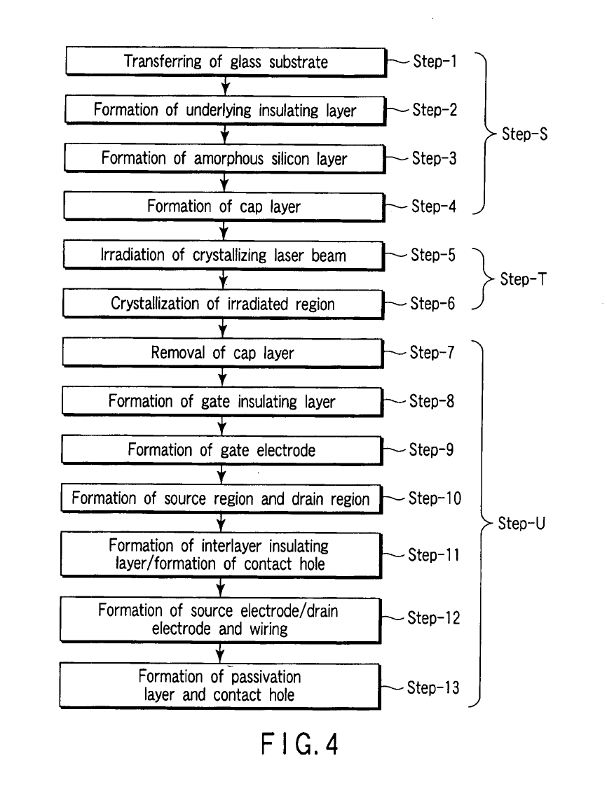

When it is desired to form a fine pattern, it is preferable to employ a process wherein exposed portions of the copper seed layer 4 are converted at first into a water-soluble copper halide such as CuClₓ or CuBrₓ by making use of a plasma etching method or a reactive ion etching method using a gas containing a halogen atom such as chlorine gas, hydrogen chloride gas, hydrogen bromide, etc., and then the copper halide is removed. In this case, since the thickness of copper seed layer 4 is small, the conversion of copper seed layer 4 into copper halide can be sufficiently executed throughout the entire thickness of the copper seed layer 4. Of course it is possible to employ a dry process such as sputter etching using argon gas, etc. On this occasion, it is preferable to employ an inorganic insulating layer or a metallic layer in place of the aforementioned resist layer 5 and, after finishing the etching of the copper seed layer, to remove the inorganic insulating layer or the metallic layer. In this manner, it is possible to obtain a pattern 4a of copper seed layer as shown in FIG. 4G.

The formation of a copper wiring pattern:

Then, as shown in FIG. 1H, a pattern of copper thin film, e.g., a copper wiring pattern 7 is formed on the copper seed layer 4 by means of electroless plating method. In contrast to electrolytic plating, formation of a wiring for applying an electric field and subsequent disconnection of the wiring are not required in the electroless plating. Further, since the device for applying an electric field is not required, it is possible to form a uniform plated film on a rectangular substrate having four sides each exceeding 1 m. The thickness of the copper wiring pattern 7 may be 400 nm for example. The copper wiring pattern 7 can be formed only on the surface of copper seed layer 4 as shown in FIG. 1H.

In this case, the copper (plated) wiring pattern 7 can be formed only on the surface of the pattern 4a of copper seed layer through an epitaxial growth. Therefore, it is more preferable that the crystal orientation of the copper seed layer 4 is (111) and that an average crystal grain diameter of the copper seed layer 4 is relatively large in order to make the copper (plated) wiring pattern 7 larger in average crystal grain diameter and to obtain the copper (plated) wiring pattern 7 of low specific resistance. It is more preferable to additionally provide a washing step for removing oxides existing on the surface of the copper seed layer 4 as a pretreatment for forming the copper wiring pattern 7 by means of electroless plating.

As for the electroless plating bath, it is preferable to employ a neutral electroless plating bath formed of a solution containing a copper compound such as copper sulfate and a cobalt salt as a reducing agent and not containing alkaline metal. However, since the resist layer is already removed, it is also possible to employ even a strong alkaline plating bath, such as a plating bath using formaldehyde as a reducing agent. Although an ordinary formaldehyde bath contains sodium hydroxide as a pH-adjusting agent, it is more preferable to employ an organic alkali rather than an inorganic alkali if the bath is to be used for the manufacturing process of a thin film transistor which is used in a liquid crystal display device, for example.

It is possible, through the formation of the copper wiring pattern 7 containing copper as a major component by means of electroless plating, to form a thin film on the surface of rectangular glass substrate of large size for liquid crystal display device where one side of the substrate 1 is as long as more than one meter.

Since the electroless plating of the copper wiring pattern 7 only on the surface of the copper seed layer 4 is effective in preventing copper from being deposited on surface portions where the deposition of copper is not required, this method can be said to be a resource-saving method. In this manner, the copper wiring pattern 7 can be formed.

Thereafter, as shown in FIG. 1I, by making use of the copper wiring pattern 7 as a mask, exposed portions of the underlying barrier 3 are removed by means of etching for example, thus forming a pattern 3a of barrier layer. As for the etching method, it is preferable to employ a plasma etching using, as an etching gas, a mixed gas comprising CF₄ gas and O₂ gas when a Ta-based barrier metal is employed as the underlying barrier layer 3 for example.

The copper wiring pattern 7 containing copper as a major component is liable to Cu-diffusion. Therefore, in order to prevent the diffusion of copper, it is more preferable, as shown in FIG. 1J, to cover the surface of copper wiring pattern 7 with an interlayer insulating layer 8 made of a material excellent in copper diffusion-preventing property such as SiN, SiC, benzocyclobutene (BCB), etc.

According to the method of forming the copper wiring pattern 7 as set forth in this embodiment, it is possible to selectively form a fine metallic wiring containing copper as a major component. Even if the copper wiring pattern 7 is constituted by a thin film having a thickness of the order of submicrons ranging from 200 to 1000 nm or so, it is possible to realize a low specific resistance of not more than 2.5 μΩ·cm. Further, even on large sized rectangular substrate 1 having four sides each exceeding 1 m, it is possible to form the copper wiring pattern 7 which is low in specific resistance.

According to the ordinary method of forming a plated layer of electrolytic copper or of electroless-plated copper, since the thickness of wiring would become as large as 1 to 30 μm or so, the crystal grain diameter thereof is caused to increase concomitant with an increase of the film thickness of the plated layer.

Meanwhile, since the wiring in a liquid crystal display device is required to be formed of a thin film having a thickness of the order of submicrons, the copper wiring pattern 7 cannot be made thick. If it is desired to minimize the specific resistance of the copper (plated) wiring pattern 7, the crystal grain diameter of the copper (plated) wiring layer 7 should be increased.

As for the means to increase the crystal grain diameter of the copper wiring layer 7, it includes (1) a method wherein the crystal grain diameter of copper seed layer 4 is increased through the annealing of the copper seed layer 4, thereby making it possible to increase the crystal grain diameter of copper plated layer 7 to be formed thereon; (2) a method wherein a electroless-plated copper layer is formed at first on the copper seed layer 4 and then the electroless-plated copper layer is annealed to enlarge the crystal grain diameter of the copper wiring layer 7; and (3) a method wherein the material and/or the crystal orientation of underlying layer 3 is controlled, thereby forming a copper seed layer 4 having a large crystal grain diameter.

The copper seed layer 4 having a large crystal grain diameter can be formed by suitably selecting the sputtering conditions when the copper seed layer 4 is formed by means of sputtering for example.

As for the method of enlarging the crystal grain diameter of copper seed layer 4 through the annealing of the copper seed layer 4, it includes a method wherein the copper seed layer 4 formed in advance is annealed in a non-oxidizing atmosphere such as a nitrogen gas atmosphere, in a reducing atmosphere containing hydrogen, or in vacuum. Namely, it is possible, as a method of enlarging the crystal grain diameter of copper seed layer 4 through the annealing of the copper seed layer 4, to employ a method wherein the copper seed layer 4 formed in advance is annealed in a nitrogen gas atmosphere at a temperature of not higher than 500° C. More specifically, in industrial viewpoints, the annealing temperature of the copper seed layer 4 should preferably be confined within the range of 200° C. to 450° C.

As for the method to enlarge the crystal grain diameter of the copper wiring layer 7 through the annealing thereof after a copper plated layer is formed on the copper seed layer 4, it is possible to employ a method wherein a copper seed layer 4 that has been formed in advance is patterned into a desired configuration, and then copper is electroless-plated on the patterned layer to form a copper wiring layer 7, which is then annealed in a non-oxidizing atmosphere. The annealing in this case should preferably be performed under the conditions of not higher than 500° C. and, in industrial viewpoints, within the range of 200° C. to 450° C. in a non-oxidizing atmosphere.

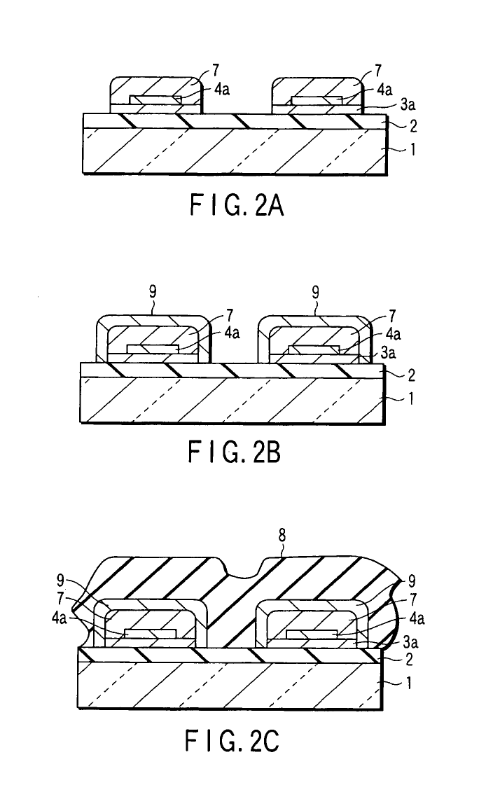

Next, there will be explained, with reference to FIGS. 2A to 2C, another embodiment wherein a layer for preventing the diffusion of copper is superimposed on the surface of the copper wiring pattern 7 in order to enhance the property of preventing the diffusion of copper from the copper wiring pattern 7. In FIGS. 2A to 2C, the same portions or components as those shown in FIGS. 1A to 1J will be identified by the same reference numbers, thereby omitting the repeated explanation thereof. Since the process up to the step shown in FIG. 1I is the same as the aforementioned embodiment, the steps to be followed after the step shown in FIG. 1I will be explained.

The state shown in FIG. 2A is the same as that of FIG. 1I showing a cross-sectional view illustrating a state where the copper wiring pattern 7 is formed. By making use of the copper wiring pattern 7 as a mask, exposed portions of the underlying barrier layer 3 are removed to form a barrier layer pattern 3a and then a copper diffusion preventing layer 9 is formed. This copper diffusion preventing layer 9 is a layer, e.g. a capping metal layer (FIG. 2B), which is designed to suppress the diffusion of copper from the copper wiring pattern 7 that has been formed on the surface (including the sidewalls) of underlying barrier layer 3. This capping metal layer 9 should preferably be formed of a layer containing cobalt or nickel as a major component (for example, CoB, NiB, etc.), which is formed by means of electroless plating. This capping metal layer 9 should preferably be formed so as to cover at least the exposed surface of copper wiring pattern 7.

Further, as shown in FIG. 2C, in order to enhance the barrier property for suppressing the diffusion of copper from the copper wiring pattern 7, a barrier layer, e.g., an interlayer insulating layer 8, which is made of, for example, SiN, SiC, BCB, etc. is formed on the surface of this capping metal layer 9.

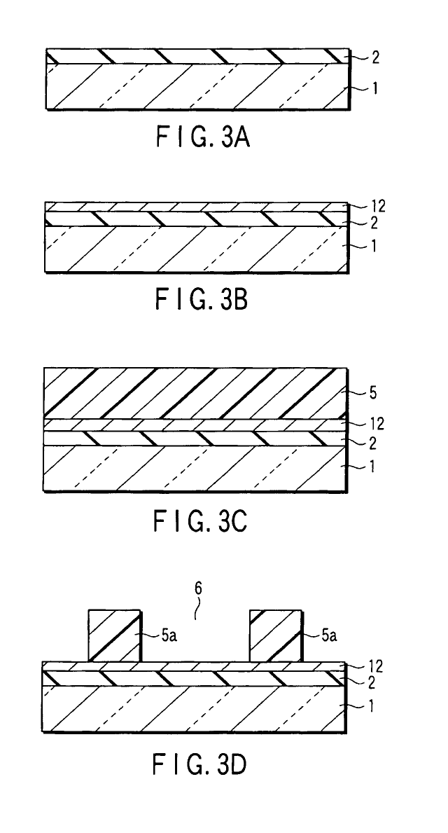

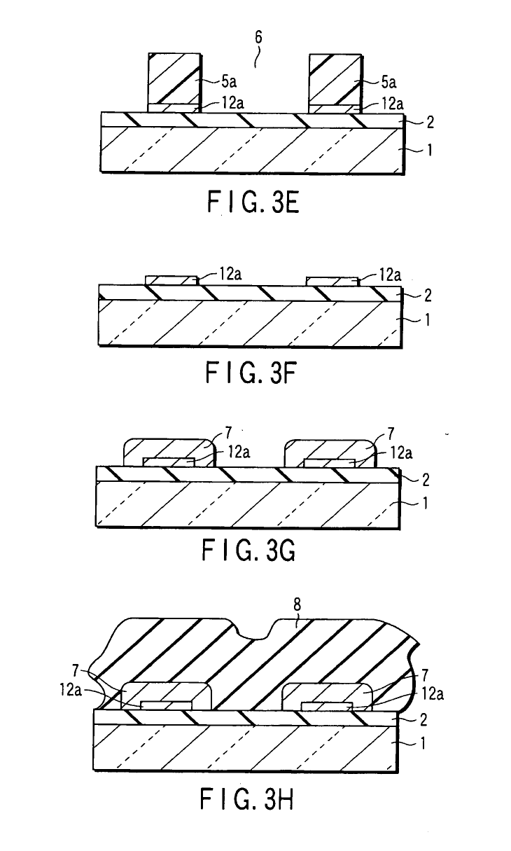

Next, there will be explained, with reference to FIGS. 3A to 3H, a further embodiment wherein the adhesion between the underlying insulating layer 2 and the copper seed layer 4 is enhanced. In FIGS. 3A to 3H, the same portions or components as those shown in FIGS. 1A to 2C will be identified by the same reference numbers, thereby omitting the repeated explanation thereof.

First of all, as shown in FIG. 3A, an underlying insulating layer 2 is formed on the surface of a substrate, for example, a glass substrate. Then, as shown in FIG. 3B, a copper alloy seed layer 12 containing copper as a major component and further containing at least one kind of metal selected from Mg, Ta, Ti, Ta, Mo, Mn, Al, W and Zr is formed as a copper seed layer on the surface of the underlying insulating layer 2. Then, the copper alloy seed layer 12 is preferably heat-treated at a temperature of about 400° C. for instance, thereby forming an oxide layer of the aforementioned additive metals exhibiting at least barrier property such as a layer of MgO, TiO₂, Ta₂O₅, etc. at the interface between the copper alloy seed layer 12 and the underlying insulating layer 2, thereby enhancing the adhesion between the underlying insulating layer 2 and the copper alloy seed layer 12.

By following the same process as explained in the embodiment shown in FIGS. 1A to 1J, the copper wiring pattern 7 may be formed on the copper alloy seed layer 12 created in this manner. Namely, as shown in FIG. 3C, a photoresist layer 5 is formed on the surface of the copper alloy seed layer 12 and then processed into a wiring pattern as shown in FIG. 3D.

Then, by making use of, as a mask, the photoresist pattern 5a that has been formed into a wiring pattern, exposed portions of the copper alloy seed layer 12 which are exposed through the opening 6 are etched away to form a wiring pattern 12a of the copper alloy seed layer 12 on the surface of the underlying insulating layer 2. Then, the photoresist pattern 5a is removed by means of etching.

Subsequently, as shown in FIG. 3G, a copper wiring pattern 7 is formed on the wiring pattern 12a of the copper alloy seed layer by means of electroless plating. Namely, a electroless plating layer constituting the copper wiring pattern 7 is formed on the wiring pattern 12a of the copper alloy seed layer. This electroless-plated layer may be formed to have a thickness of 400 nm for example.

Further, as shown in FIG. 3H, an interlayer insulating layer 8 made of a material excellent in barrier property to the diffusion of copper from the copper wiring pattern 7 is formed on the surface of each copper wiring pattern 7 as well as on the openings formed in the copper wiring pattern 7. The copper wiring pattern 7 can be formed in this manner.

As the means to suppress the diffusion of copper from the copper wiring pattern 7, the interlayer insulating layer 8 may be formed as a single layer or as a 2-ply layer. An embodiment where the suppression of diffusion of copper is effected through such a 2-ply layer will be realized as shown in FIGS. 2A to 2C. Namely, as shown in FIG. 2A, the exposed surface (including the exposed sidewalls) of the copper wiring pattern 7 which has been formed in advance is covered through the formation of a layer of material which is capable of suppressing the diffusion of copper as shown in FIG. 2B, thus forming a first layer. This layer of material for suppressing the diffusion of copper may be the capping metal layer 9 for instance. This capping metal layer 9 can be formed by electroless-plating a material containing cobalt or nickel as a major component (for example, CoB, CoWB, NiB, NiWB, etc.). On this first capping metal layer 9 formed in this manner, a second layer of the interlayer insulating layer 8 is formed to form a copper diffusion preventing layer of 2-ply structure.

Alternatively, a second layer of the interlayer insulating layer 8 made of SiN, SiC, BCB, etc. may be formed on the capping metal layer 9.

It is needless to say that the copper wiring pattern 7 to be formed in this manner can be applied not only to the creation of signal lines, power source lines and scanning lines to be formed on the substrate of a semiconductor integrated circuit, of an LCD, and of an organic LED such as an active matrix type organic LED, but also to the creation of the electrodes of TFT, the peripheral wiring thereof and the wiring in a peripheral driving circuit formed on the same substrate. According to the method of forming the wiring as set forth in this embodiment, it is possible to selectively form a metallic wiring containing copper as a major component and also to form such a fine wiring pattern as demanded in the wiring of peripheral driving circuit.

The method of forming the copper wiring layer as set forth in this embodiment is featured in that it comprises steps of forming a predetermined pattern of copper seed layer on a substrate; and forming a copper wiring pattern on the pattern of copper seed layer by means of electroless plating. According to this method, since the copper wiring pattern is formed by means of electroless plating, the employment of electrodes for plating is no longer required, so that even if the area to be plated is large, it is possible to reliably form a copper plating layer on the copper seed layer and, at the same time, it is no longer required to perform the separation of copper wirings in a subsequent step. Since the copper plating layer is formed only on the copper seed layer, it is possible to prevent copper from being deposited on a region which does not necessitate the deposition of copper, thereby enhancing the utilization efficacy of copper and, at the same time, the copper wiring layer can be formed throughout the entire conductive region of large area.

The aforementioned step of forming a pattern of copper seed layer can be performed by a series of steps wherein a copper seed layer is formed at first on a substrate, and then the copper seed layer is selectively etched away to transform it into a predetermined wiring pattern. According to this method, since a copper wiring layer is formed through electroless plating after finishing the patterning of a copper seed layer, it is possible to effectively inhibit fluctuation of film thickness resulting from differences in width of pattern and minimize the disconnection of wiring as compared with the case where a plating film is to be formed inside a trench. Furthermore, since the cross-sectional configuration of wiring is not rectangular but nearly semicircular, the coverage property of overlying interlayer insulating layer becomes excellent, thus making it possible to minimize the generation of leak current between a lower wiring layer and an upper wiring layer.

Next, there will be explained, with reference to FIGS. 4 to 7, a further embodiment wherein the present invention is applied to the method of manufacturing a semiconductor device. In FIGS. 4 to 7, the same portions or components as those shown in FIGS. 1A to 3H will be identified by the same reference numbers, thereby omitting the repeated explanation thereof. This embodiment is directed to the method of manufacturing a semiconductor device provided, on an insulating substrate thereof, with a thin film transistor (TFT) and a wiring.

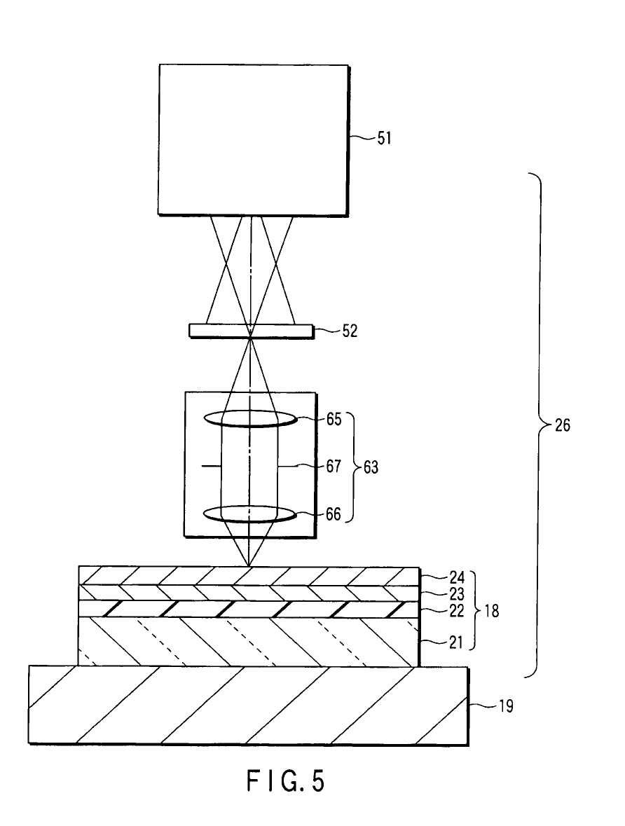

First of all, the manufacturing process “Step-S” of a substrate 18 for crystallization shown in FIG. 5 will be explained with reference to the flowchart shown in FIG. 4. A glass substrate 21 made of quartz or non-alkali glass is transferred to a predetermined location inside the chamber of plasma CVD device and set in place (Step 1). Then, an underlying insulating layer 22, for example a silicon nitride layer, is formed through vapor-phase growth on the glass substrate 21 by means of plasma CVD method (Step 2). Then, an amorphous silicon layer to be crystallized or non-monocrystalline semiconductor layer made of a polycrystalline silicon layer (in this embodiment, an amorphous silicon layer 23) is formed through vapor-phase growth on the silicon nitride layer 22 to a thickness ranging from 30 nm to 300 nm (for example, about 200 nm in this embodiment) by means of plasma CVD method (Step 3). Thereafter, in order to create a region of large crystal grain diameter on the amorphous silicon layer 23, a cap layer excellent in transmission to incident light and in heat accumulating property, such as silicon oxide layer 24 for instance, is formed on the amorphous silicon layer 23 to a thickness ranging from 10 nm to 1000 nm (for example, about 260 nm in this embodiment) by means of plasma CVD method. This cap layer 24 is an insulating layer, which is capable of accumulating heat and hence capable of alleviating the rate of temperature drop of non-monocrystalline semiconductor layer on the occasion of irradiating laser beam for the crystallization of silicon layer. In this manner, a crystallizing substrate (i.e. a substrate to be crystallized) 18 is manufactured (Step 4).

Next, a process for crystallization “Step-T” is performed. First of all, the crystallizing substrate 18 thus manufactured is transferred to a predetermined region of a sample substrate table 19 of a crystallizing device 26 and set in place. Then, an excimer laser flux exhibiting a light intensity distribution having a reverse peak pattern is irradiated to a predetermined crystallization position of the crystallizing substrate 18 that has been transferred to the crystallizing device 26, thus irradiating the laser flux to the amorphous silicon layer 23 after permeating through the silicon oxide layer 24 employed as a cap layer (Step 5). As a result, a region of large crystal grain diameter is formed on this laser flux-irradiated region (Step 6). In this irradiation step, the laser flux-irradiated region is successively shifted to other predetermined regions while successively shifting the amorphous silicon layer 23 to thereby perform the crystallization process.

The aforementioned excimer laser beam may be KrF excimer laser having an energy density of 500 mJ/cm². The information regarding the region for crystallization is stored in advance in a computer of the crystallizing device 26. Through the instruction from this computer, the region for crystallization on the crystallizing substrate 18 is automatically placed in position and laser beam for crystallization is irradiated thereto. This laser beam-irradiating position is successively shifted to thereby successively perform the crystallization, thus finishing the process of crystallization “Step-T”.

Namely, in the process of crystallization “Step-T”, an excimer pulse laser beam exhibiting a light intensity distribution “R” having a reverse peak pattern is irradiated to the surface of cap layer 39 by making use of a phase-modulated excimer laser crystallization method. Due to the irradiation of this pulse laser beam, the irradiated region of the amorphous silicon layer 23 is heated to a high temperature and fused. Due to this high temperature, the underlying insulating layer 22 and the cap layer 24 are heated and hence the heat is accumulated in these underlying insulating layer 22 and cap layer 24. The aforementioned fused region is permitted to become lower in temperature during the cut-off period of the pulse laser beam. As a result, owing to the aforementioned accumulated heat, the position of solidification is permitted to move slowly to the lateral direction (horizontal direction), thus generating crystal growth and forming a region of large crystal grain diameter.

As a result, part or entire region of the amorphous silicon layer 23 is crystallized and hence converted into a crystalline silicon layer. The irradiation of the pulse laser beam exhibiting a light intensity distribution “R” having a reverse peak pattern may be performed only once or twice or more against the same region or in an overlapping manner so that part of the region once irradiated is again irradiated by the pulse laser beam. Further, the irradiation of the pulse laser beam may be employed in combination with the irradiation of light from flash lamp. The amorphous silicon layer 23 thus crystallized in this manner is defined as a crystalline silicon layer in this specification.

Next, there will be explained a process “Step-U” for forming a semiconductor device such as a TFT in the semiconductor thin film after finishing the process of crystallization “Step-T”. The crystallizing substrate 18 which has undergone the process of crystallization “Step-T” is provided, on the surface thereof, with a silicon oxide layer (SiO₂) constituting the cap layer 24.

In this embodiment, the cap layer 24 that has been formed in the region of large crystal grain diameter in the previous process for forming a TFT is removed by means of etching (Step 7). The crystalline silicon layer which has undergone the process of crystallization “Step-T” is permitted to expose on the surface of crystallizing substrate 18 where the cap layer 24 has been removed.

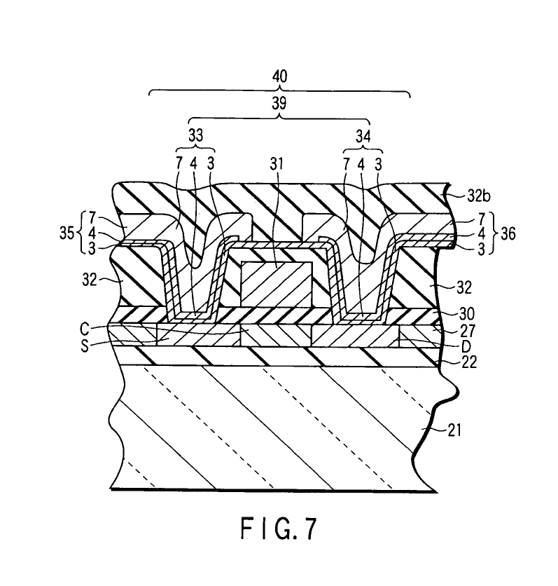

Then, a semiconductor device such as a thin film transistor (TFT) is formed on the glass substrate 21 where the process of crystallization “Step-T” has been finished. First of all, the glass substrate 21 is transferred into a plasma CVD reaction chamber and then, as shown in FIG. 7, a silicon oxide film for forming a gate insulating layer 30 is formed on the exposed surface of the crystalline silicon layer 27 of the transferred glass substrate 21 (Step 8). The gate insulating layer 30 may be a silicon oxide film having a thickness of 30 nm for instance.

Thereafter, a gate electrode 31 made of MoW is formed at a predetermined position for wiring pattern on the gate insulating layer 30 (Step 9).

By making use of this gate electrode 31 as a mask, an impurity ion is injected at a high concentration into the crystallized region. In this ion implantation, phosphorus for example is employed as the impurity ion when the transistor is N-channel, and boron for example is employed as the impurity ion when the transistor is P-channel. Subsequently, the resultant substrate is subjected to annealing (for example, 550° C. for one hour) in a nitrogen gas atmosphere to activate the impurity, thus forming a source region “S” and a drain region “D” in the crystallized region. As a result, a channel region “C” where carrier is enabled to move is formed between the source region “S” and the drain region “D” (Step 10).

Then, an interlayer insulating layer 32 consisting of a laminate structure formed of SiO₂/SiN or SiO₂/BCB is formed on the surfaces of the gate insulating layer 30 and the gate electrode 31. Further, contact holes for forming a source electrode 33, a drain electrode 34 and wirings 35 and 36 to be connected with these electrodes 33, 34 are formed in this interlayer insulating layer 32 (Step 11).

Thereafter, a laminate structure composed of an underlying barrier layer 3, a copper seed layer 4 and a copper wiring pattern 7 all explained with reference to FIGS. 1A-1J and constituting the source electrode 33 as well as the drain electrode 34 is formed in these contact holes explained above. Furthermore, by making use of photolithography technique, the wirings 35 and 36, each composed of an underlying barrier layer 3 having a predetermined pattern, a copper seed layer 4 having a predetermined pattern, and a copper wiring pattern 7, are formed also on the surface of the interlayer insulating layer 32, thereby manufacturing a thin film transistor (TFT) 39 and hence a semiconductor device 40 provided with the thin film transistor (TFT) 39 (Step 12).

Then, a passivation layer 41 made of SiN or a laminate consisting of SiN and BCB is formed on the surface of the TFT 39. Thereafter, a contact hole is formed at a predetermined region of the electrode pad, etc. of the passivation layer 41 (Step 13). This electrode pad may be also constituted by a laminate structure composed of the underlying barrier layer 3, the copper seed layer 4 and the copper wiring pattern 7 all explained with reference to FIGS. 1A-1J.

In the foregoing embodiment, although a MoW layer is employed as a gate electrode, the gate electrode may be also constituted by a laminate structure composed of the underlying barrier layer 3, the copper seed layer 4 and the copper wiring pattern 7 all explained with reference to FIGS. 1A-1J or to FIGS. 2A-3H. The wiring pattern may be configured as electrodes, pads or wiring.

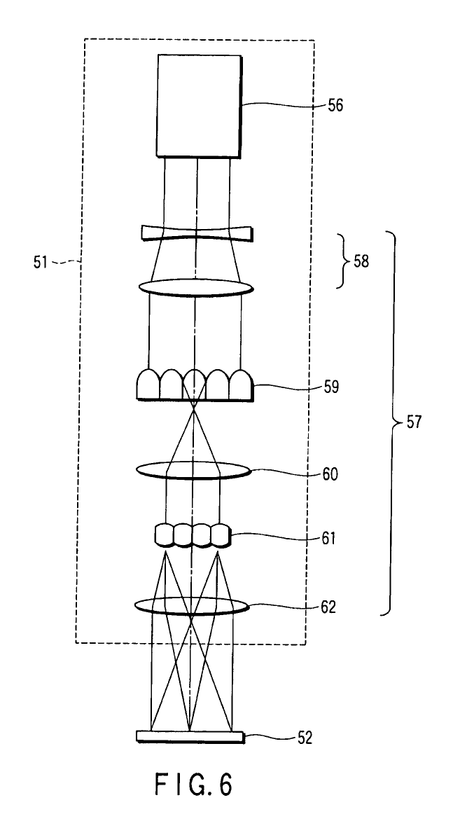

Next, the crystallizing device 26 to be employed in the crystallizing process “Step-T” explained in the above embodiment will be more specifically explained with reference to FIGS. 5 and 6. This crystallizing device 26 is composed of an illumination system 51, a phase-modulating element 52 placed on the optical axis of the illumination system 51, an image-forming optical system 53 placed on the optical axis of the phase-modulating element 52, and a sample substrate table 19 for supporting the crystallizing substrate 18 which is disposed on the optical axis of the image-forming optical system 53.

The illumination system 51 is formed of an optical system shown in FIG. 6 and constituted, for example, by a light source 56 and a homogenizer 57. The light source 56 is provided with a XeCl excimer laser beam source for emitting a light having a wavelength of 308 nm. Incidentally, as for the light source 56, it is also possible to employ other kinds of excimer laser such as a KrF excimer laser beam source for emitting a pulse beam having a wavelength of 248 nm or a ArF laser for emitting a pulse beam having a wavelength of 193 nm. Further, the light source 56 may be formed of a YAG laser beam source. The light source 56 may be formed of any other suitable light source which is capable of outputting an energy sufficient to fuse a non-monocrystalline semiconductor film such as the amorphous silicon layer 23. On the optical axis of laser beam to be emitted from this light source 56, there is disposed a homogenizer 57.

This homogenizer 57 is composed of, for example, a beam expander 58, a first fly-eye lens 59, a first condenser optical system 60, a second fly-eye lens 61, a second condenser optical system 62, which are disposed successively on the optical axis of the laser beam to be emitted from the light source 56. This homogenizer 57 is designed to homogenize the intensity of light throughout the cross-section of the laser beam flux that has been irradiated from the light source 56 as well as the incident angle of the laser beam flux to be transmitted into the phase-modulating element 52.

Namely, in the illumination system 51, the laser beam emitted from the light source 56 is expanded at a beam expander 58 and then permitted to enter into the first fly-eye lens 59. A plurality of light sources are created on the rear focal surface of this first fly-eye lens 59, and the fluxes from this plurality of light sources are transmitted, through the first condenser optical system 60, to the incident plane of the second fly-eye lens 61, thus illuminating the incident plane in a superimposed manner. As a result, a more increased number of light sources than that to be created on the rear focal surface of this first fly-eye lens 59 are created on the rear focal surface of this second fly-eye lens 61. The light fluxes from a large number of light sources formed on the rear focal surface of this second fly-eye lens 61 are transmitted, through the second condenser optical system 62, to the phase-modulating element 52, thus illuminating it in a superimposed manner.

As a result, a first homogenizer is constructed from the first fly-eye lens 59 and first condenser optical system 60 of the homogenizer 57, this first homogenizer performing the homogenizing treatment with respect to the incident angle of the laser beam entering into the phase-modulating element 52. Further, a second homogenizer is constructed from the second fly-eye lens 61 and second condenser optical system 62, this second homogenizer performing the homogenizing treatment of the intensity of light at each location within the plane of the phase-modulating element 52 with respect to the laser beam transmitted from the first homogenizer and homogenized in incident angle. In this manner, a laser beam exhibiting a substantially uniform light intensity distribution is created by the illumination system 57 and this laser beam is transmitted to the phase-modulating element 52.

This phase-modulating element 52, for example a phase shifter, is an optical element which is capable of phase-modulating the light emitted from the homogenizer 57 so as to emit a laser beam exhibiting a light intensity minimum distribution having a reverse peak pattern. In this light intensity minimum distribution, the abscissa denotes a location (a position at the irradiation surface) and the ordinate denotes a light intensity (energy). As for the optical system for obtaining a light intensity minimum distribution having a reverse peak pattern, there are two cases where a recessed/projected pattern formed in a transparent substrate, for example a quartz glass substrate is a line-and-space pattern and an area-modulated pattern.

The phase shifter is designed to provide a transparent body, for example a quartz substrate having step portions (recessed/projected portions) to thereby make it possible to generate the diffraction and interference of laser beam at the boundaries of step portions, thus providing a laser beam intensity with a periodic special distribution. The phase shifter is constructed for example such that a phase difference is provided at an angle of 180 degrees right- and left-wise with the step portion: x=0 being defined as a boundary. Generally, when the wavelength of laser beam is defined as λ and when a transparent medium having a refractive index of “n” is to be formed on a transparent substrate so as to provide a phase difference of 180 degrees, the film thickness “t” of the transparent medium can be given by: t=λ/2(n−1). Since the wavelength of XeCl excimer laser beam is 308 nm, when the refractive index of quartz substrate is assumed as being 1.46, it is required to form a step portion of 334.8 nm by making use of photoetching for instance in order to create a phase difference of 180 degrees.

Further, when an SiNₓ film is employed as a transparent medium and formed by means of PECVD, LPCVD, etc, the SiNₓ film should be formed on a quartz substrate to a thickness of 154 nm, assuming that the refractive index of the SiNₓ film is 2.0. Then, the SiNₓ film is subjected to photoetching to form step portions. The intensity of the laser beam that has passed through a phase shifter provided with a phase difference of 180 degrees for example would indicate a pattern of periodic difference in intensity (line-and-space).

In this embodiment, the mask where step portions are repeatedly and periodically formed therein is a periodic phase shifter. The width of phase shift pattern and the intervals between patterns may be both 3 μm for example. The phase difference may not necessarily be 180 degrees. Namely, the phase difference may be suitably selected as long as it is possible to provide the laser beam with a difference in intensity.

The laser beam that has been phase-modulated at the phase-modulating element 52 is transmitted, through the image-forming optical system 53, to the crystallizing substrate 18. In this case, this image-forming optical system 53 is disposed so as to optically conjugate the patterning plane of the phase-modulating element 52 with the crystallizing substrate 18. In other words, the height of the sample substrate table 19 is adjusted such that the crystallizing substrate 18 can be set at a plane (imaging plane of the image-forming optical system 53) which is optically conjugate with the patterning plane of the phase-modulating element 52. The image-forming optical system 53 is provided with an aperture diaphragm 67 between a group of positive lens 65 and another group of positive lens 65. This image-forming optical system 53 is formed of an optical lens which is designed to transfer the image of the phase-modulating element 52 to the crystallizing substrate 18, the scale of image of the phase-modulating element 52 on this occasion being reduced to ⅕ for example or not reduced at all.

The aperture diaphragm 67 is composed of a plurality of aperture diaphragms differing in size of aperture (light-permeating portion). These aperture diaphragms 67 may be constructed exchangeably relative to optical path. Alternatively, the aperture diaphragm 67 may be provided with an iris diaphragm which is capable of continuously changing the size of the aperture. In any case, the size of the aperture of aperture diaphragm 67 (i.e., the numerical aperture “NA” on the image side of the image-forming optical system 4) is set in such a way that a desired light intensity distribution can be generated on the surface of semiconductor film of the crystallizing substrate 18 as described hereinafter. Incidentally, the image-forming optical system 53 may be a refraction type optical system, a reflection type optical system or a refractive reflection type optical system.

As shown in FIG. 5, the crystallizing substrate 18 is formed of a laminate composed of a silicon oxide layer acting as the underlying insulating layer 22, an amorphous silicon layer 23 employed as a layer to be crystallized, and a silicon oxide layer acting as the cap layer 24, all of these layers being successively formed on the surface of the glass substrate 21 for liquid crystal display for instance, by means of chemical vapor deposition (CVD) or sputtering.

The amorphous silicon layer 23 is a film to be subjected to crystallization treatment, the thickness thereof being selected from the range of 30 to 250 nm for instance. The cap layer 24 is capable of accumulating the heat to be generated as the amorphous silicon layer 23 is fused during the crystallizing process. This heat-accumulating action contributes to the creation of a region of large crystal grain size. This cap layer 24 is formed of an insulating film such as a silicon oxide film (SiO₂) having a thickness ranging from 100 nm to 400 nm (for example, 300 nm).

The crystallizing substrate 18 is automatically transferred to the top surface the sample substrate table 19 of the crystallizing device 26 and set in a predetermined place and held in place by means of vacuum chuck or electrostatic chuck.

Next, the crystallization process will be explained with reference to FIGS. 5 and 6. The pulse laser beam emitted from the laser beam source 56 is transmitted to the homogenizer 57 through which the homogenization of optical intensity within the cross-section of laser beam as well as the homogenization of the incident angle to the phase-modulating element 52 is performed. Namely, in this homogenizer 57, the laser beam entering therein from the light source 56 is expanded in horizontal direction to create a linear laser beam (for example, 200 mm in length) exhibiting also a uniform light intensity distribution. For example, a plurality of cylindrical lens elongated in X-direction are arrayed side by side in Y-direction, thereby creating a plurality of light fluxes arrayed in Y-direction. Then, by making use of another cylindrical lens elongated in X-direction, each of these light fluxes is redistributed. Likewise, a plurality of cylindrical lens elongated in Y-direction are arrayed side by side in X-direction, thereby creating a plurality of light fluxes arrayed in X-direction. Then, by making use of another cylindrical lens elongated in Y-direction, each of these light fluxes is redistributed.

This laser beam may be a XeCl excimer laser beam having a wavelength of 308 nm wherein the duration of pulse per shot is 20 to 200 ns. When a pulse laser beam is irradiated to the phase-modulating element 52 under the aforementioned conditions, the pulse laser beam transmitted into the phase-modulating element 52 that has been configured periodically is modulated by the step portions, thereby generating the diffraction and interference of light. As a result, the phase-modulating element 52 acts to generate a light intensity distribution having a reverse peak pattern changing periodically and exhibiting differing light intensities.

This light intensity distribution has a reverse peak pattern exhibiting differing light intensities ranging from a minimum light intensity to a maximum light intensity and is capable of outputting a sufficiently strong laser beam intensity to fuse the amorphous silicon layer 23. The pulse laser beam that has passed through the phase-modulating element 52 is caused to focus at the crystallizing substrate 18 by means of the image-forming optical system 53 and transmitted to the amorphous silicon layer 23.

Namely, most of the pulse laser beam transmitted in this manner is permitted to permeate through the cap layer 24 and absorbed in the amorphous silicon layer 23. As a result, the irradiated region of the amorphous silicon layer 23 is heated and fused. The heat generated during this fusing step is permitted to accumulate in the silicon oxide film constituting the cap layer 24 and also in the silicon oxide film constituting the underlying insulating layer 22.

In the irradiation cutoff period of the pulse laser beam, the irradiated region of the amorphous silicon layer 23 is prevented from being rapidly cooled due to the heat accumulated in the silicon oxide film of the cap layer 24 and of the underlying insulating layer 22 formed, respectively, on the top and bottom surfaces of the amorphous silicon layer 23. As a result, the irradiated region of the amorphous silicon layer 23 is cooled at a very slow rate. On this occasion, the cooling rate of the irradiated region would be dependent on the light intensity distribution having a reverse peak pattern which will be created by the phase-modulating element 52. As a result, the crystal growth would take place successively in the lateral direction.

In other words, the location of solidification in the fused region within the irradiated region is enabled to gradually move from a low temperature side to a high temperature side. Namely, the crystal growth would take place in the lateral direction from the crystal growth-initiating region to the crystal growth-terminating region. In this manner, the crystallization process by making use of laser beam of one pulse is accomplished. The crystallized region where the aforementioned crystal growth has taken place is large enough to enable a single or a plurality of TFTs can be formed therein.

The crystallizing device 26 is constructed such that the crystallizing region of the amorphous silicon layer 23 is successively and automatically subjected to the irradiation of pulse laser beam according to the program stored in advance, thereby successively creating crystallized regions. The movement of the amorphous silicon layer 23 for the next crystallizing region thereof can be carried out through a relative movement between the crystallizing substrate 18 and the light source 56. For example, the position of irradiation can be suitably selected by moving the sample substrate table 19.

When the crystallizing region is selected and the alignment thereof is accomplished, the next pulse laser beam is irradiated to the crystallizing region. By repeating the shot of laser beam in this manner, the crystallization of large area of the crystallizing substrate 18 can be executed, thus finishing the crystallization process.

This embodiment can be applied to the creation of signal lines, power source lines, scanning lines electrodes of TFT, and the peripheral wiring thereof to be formed on the substrate, and of the wiring in a peripheral driving circuit formed on the same substrate of not only the semiconductor device, but also an LCD and an organic LED device (OLED) such as an active matrix type organic LED device (OLED). Although the above embodiment has been explained on the basis of a transistor having a crystalline silicon semiconductor layer, it is of course possible to apply the present invention to the creation of electrodes and peripheral wirings of amorphous silicon transistor having a polycrystalline semiconductor layer or having a gate electrode below a semiconductor layer. If it is desired to apply the present invention to the creation of the gate electrode of an amorphous silicon transistor with lower gate structure, the gate insulating film to be formed on this gate electrode should preferably be formed from a silicon nitride layer excellent in barrier property or a laminate structure consisting of a silicon oxide layer and a layer of hafnium oxide (HfO₂), etc.

As explained above, according to the above embodiments, it is possible to obtain a low resistance copper wiring having a low specific resistance of, for example, 2.5 μΩ·cm or less. In particular, it is possible to construct a semiconductor device such as a thin film transistor and a thin film transistor circuit. Further, it is possible to form a copper wiring having a desired cross-sectional area. Furthermore, it is possible to form a copper wiring layer in every conductive regions all over a wide region even if the substrate is large in scale.

What is claimed is:

1. A method for manufacturing a thin film transistor having a semiconductor layer on a glass substrate, comprising:
(a) forming an underlying insulating layer on the glass substrate;
(b) forming an underlying barrier layer on the underlying insulating layer;
(c) forming a patterned seed layer on the underlying barrier layer;
(d) forming a copper wiring pattern on a surface of the seed layer by means of electroless plating;
(e) patterning the underlying barrier layer by using the copper wiring layer as a mask; and
(f) forming an insulating layer for covering a surface of the copper wiring pattern.

2. The method according to claim 1, wherein the underlying insulating layer includes a silicon nitride film.

3. The method according to claim 1, wherein the underlying barrier layer includes at least one material selected from Ta, TaN, TiN, and TaSiN.

4. The method according to claim 1, wherein the seed layer contains copper as a major component.

5. The method according to claim 4, wherein the seed layer contains at least one kind of metal selected from Mg, Ta, Ti, Mo, Mn, Al, W and Zr.

6. The method according to claim 5, further comprising forming a oxide layer between the seed layer and the underlying insulating layer.

7. The method according to claim 6, wherein the oxide layer is selected from MgO, TiO₂ and TaO₂.

8. The method according to claim 1, wherein a crystal face of the seed layer is oriented mainly in (111) plane.

9. The method according to claim 1, wherein the copper wiring layer has a thickness of 200 nm to 1000 nm and a specific resistance of 2.5 μΩ·cm or less.

10. The method according to claim 1, further comprising annealing the copper wiring layer in a non-oxidizing atmosphere at a temperature of not higher than 500° C.
